(19) United States
(12) Patent Application Publication
(10) Pub. No.: US 2005/0048799 A1
(43) Pub. Date: Mar. 3, 2005

(54) Film forming material, film forming method, and film

(75) Inventors: Hideaki Machida, Yamanashi (JP); Takeshi Kada, Yamanashi (JP); Masato Ishikawa, Yamanashi (JP); Yoshio Ohshita, Aichi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Tri Chemical Laboratories Inc., Kitatsuru-Gun (JP)

(21) Appl. No.: 10/895,827

(22) Filed: Jul. 22, 2004

(30) Foreign Application Priority Data
Aug. 26, 2003 (JP) 2003-301518

(51) Int. Cl. H01L 21/22; H01L 21/469; H01L 21/8242; H01L 21/336; H01L 21/38

(52) U.S. Cl. 438/785; 438/240; 438/770; 438/585

(57) ABSTRACT

A technique is provided of creating high-purity amorphous gate oxides film through a CVD process. In the technique of creating Hf—Si oxide films through the chemical vapor deposition process, Si(OR)₄ and Hf(NR′R″)₄ are used.

### BACKGROUND OF THE INVENTION

The present invention relates to a material for forming, for example, gate oxide films used for semiconductor elements, to a method for forming gate oxide films using the material and through a chemical vapor deposition process, and to gate oxide films used for semiconductor elements.

Recently, the progress in the semiconductor field is remarkable. For example, LSIs are being converted into ULSIs. Miniaturization is being developed to improve the signal processing speed or based on other demands. Particularly, the spacing between the source and the drain is being shortened. In the operations of semiconductor elements, a predetermined gate dielectric strength must be maintained. The current trend is to reduce the thickness of the gate oxide film to store a large electric charge in a small area thereof.

Currently, the gate oxide film is formed of SiO₂. It is expected that the thickness of the gate oxide film will be reduced to 10 nm or less. When the thickness of the gate oxide film is 3 nm or less, for example, 3 nm, 2 nm, or 1.5 nm, the electric charge accumulated between the source and the drain can pass through the gate oxide film. Such increased leak tunnel current will induce an adverse effect on the operation of a semiconductor element.

Various oxide films have been proposed to solve such a problem. The following characteristics are required for the oxide film.

(1) The oxide film has a high dielectric constant.

(2) The oxide film is formed without impairing a semiconductor substrate and others, for example, without oxidizing the lower silicon layer.

(3) A film of several nm in thickness can be simply formed with good reproducibility.

Hf oxide films, for example, have been proposed in terms of dielectric constant. That is, Hf creates a stable silicate on an interface to Si, thus stabilizing the interface to silicon. Moreover, the Hf oxide film has a higher dielectric constant so that the effectiveness thereof is expected.

However, the Hf oxide film has a polycrystalline structure. Particularly, it was reported that the Hf oxide film makes a pillar polycrystalline structure perpendicular to the substrate on which a film is formed. For that reason, when the gate oxide film is formed with such an oxide film, it is predicted that the electric charges accumulated between the source and the drain pass through the pillar crystalline lump in the oxide film.

Converting a Hf oxide film into amorphous has been proposed. For example, it was confirmed that the Hf film is converted in an amorphous state by adding Si in the Hf film.

A target formed of HfSi_{0.8-1.2}, acting as a gate oxide film forming material, to form a Hf—Si oxide film through sputtering has been proposed (Japanese Patent Laid-open Publication No. 2002-83955).

Moreover, a target formed of HfSi_{2.05-3.0}, acting as a gate oxide film forming material, has been proposed (Japanese Patent Laid-open Publication No. 2002-270829).

A target formed of HfSi_{0.05-0.37} has been proposed as a gate oxide film forming material (Japanese Patent Laid-open Publication No. 2003-92404).

However, sputtering takes much time to form gate oxide films. That is, the film formation becomes costly.

The sputtering process causes poor step coverage. For example, when a film is formed on a substrate, of which the surface is not flat and is unevenness, the thickness of the film deposited on the bottom of a recess portion differs from the thickness of the film deposited on the vertical side-wall or on protrusion. In a serious case, no film may be formed over any one of the above-mentioned three portions.

Moreover, the sputtering process may badly damage the substrate.

Accordingly, the procedure of forming gate oxide films through the sputtering process is not preferable.

A chemical vapor deposition (CVD) method is known as a film forming method. It has been tried to form Hf—Si oxide films through the CVD method.

The present inventor proposed the technique on Hf—Si oxide films (refer to Japanese Patent Laid-open Publication No. 2003-124460). Namely, the technique of forming an oxide film made of Hf—Si—O—N through the CVD process has been proposed. In this proposal, Hf(N(C₂H₅)₂)₄ and((C₂H₅)₂N)₃SiH, for example, are used to form an oxide film formed of Hf(23.3%)-Si(10%)-O(64%)-N(2.7%) through the CVD process.

According to the proposal, as the concentration of Si in an oxide film increases, the concentration of N increases.

### SUMMARY OF THE INVENTION

The problem to be solved by the present invention is to provide a technique of forming Hf—Si series oxide films using a chemical vapor deposition process, without using the sputtering process. The sputtering process may invite a higher film forming cost because of the long film-forming time and may provide poor step coverage and may highly damage the substrate.

Particularly, an object of the present invention is to provide a technique of forming a Hf—Si—O film through the CVD process, wherein the concentration of impurity component in the film is low, for example, the concentration of C is 1% or less, and the concentration of Hf or Si is high.

Moreover, an object of the present invention is to provide a technique of forming a gate oxide film made of a Hf—Si—O through the CVD process, wherein the concentration of impurity component in the film is low, for example, the concentration of C is 1% or less, and the concentration of Hf or Si is high.

In order to solve the above-mentioned problems, a method for forming Hf—Si oxide films through a chemical vapor deposition process is applied. One or more chemical compounds represented with Si(OR)₄, where R is a hydrocarbon group, are used as said Si source. One or more chemical compounds represented with Hf(NR′R″)₄, where R′, R″ is a hydrocarbon group or a silicon series compound group, each which has the same type or a different type, are used as said Hf source.

The method for forming films through a chemical vapor deposition process comprises the steps of supplying Si(OR)₄, where R is a hydrocarbon group; supplying Hf(NR′R″)₄, where R′, R″ is a hydrocarbon group or a silicon series compound group, each which has the same type or a different type; and decomposing a chemical compound supplied in said supply steps to deposit Hf and Si on a substrate and thus forming a Hf—Si oxide film on said substrate.

Moreover, in a film formed through a chemical vapor deposition process, one or more chemical compounds represented with Si(OR)₄, where R is a hydrocarbon group, are used as a Si source; and one or more chemical compounds represented with Hf(NR′R″)₄, where R′, R″ is a hydrocarbon group or a silicon series compound group, each which has the same type or a different type, are used as a Hf source. The film contains Hf, Si and O as principal components and contains C having a trace amount of less than one atom %.

Moreover, a film is formed by the steps of supplying Si(OR)₄, where R is a hydrocarbon group; supplying Hf(NR′R″)₄, where R′, R″ is a hydrocarbon group or a silicon series compound group, each which has the same type or a different type; and decomposing a chemical compound supplied in the supply steps to deposit Hf and Si on a substrate and thus forming a Hf—Si oxide film on the substrate. The film contains Hf, Si and O as principal components and contains C having a trace amount of less than one atom %.

Moreover, in a film forming material being a material for forming a film through a chemical vapor deposition process, the film forming material contains Si(OR)₄, where R is a hydrocarbon group, and Hf(NR′R″)₄, where R′, R″ is a hydrocarbon group or a silicon series compound group, each which has the same type or a different type.

According to the present invention, the Si(OR)₄ and said Hf(NR′R″)₄ are supplied simultaneously or separately. Particularly, the Si(OR)₄ and said Hf(NR′R″)₄ are supplied simultaneously.

The film forming step is carried out in an oxidizing atmosphere.

Particularly, the film is a semiconductor gate oxide.

R in the Si(OR)₄ is an alkyl group having, particularly, a carbon number of 1 to 12 (preferably, 1 to 5). The Si(OR)₄ is preferably a chemical compound seleted from Si(OC₂H₅)₄ and Si(OCH₃)₄.

R′, R″ in said Hf(NR′R″)₄ is an alkyl group having, particularly a carbon number of 1 to 12 (preferably, 1 to 5). The Hf(NR′R″)₄ is preferably a chemical compound seleted from Hf(N(C₂H₅)₂)₄, Hf(N(CH₃)₂)₄, and Hf(N(C₂H₅)CH₃)₄.

Most preferably, Hf(N(C₂H₅)₂)₄ and Si(OC₂H₅)₄ are used.

A preferable supply ratio (weight ratio) of Hf(NR′R″)₄ and Si(OR)₄ is 1:100 to 1000:1 (=the former:the latter). Particularly, a preferable supply ratio (weight ratio) is 1:50 to 100:1 (=the former:the latter). This ratio is selected to obtain a gate oxide film (or a gate oxide film made of a Hafnium silicon oxide film) having a preferable characteristic.

The present invention provides semiconductor elements having the above-mentioned films.

The oxide film according to the present invention is formed through the CVD process in which the Si(OR)₄ and the Hf(NR′R″)₄ are used. Consequently, the concentration of an impurity such as C in the resultant film is extremely low, that is, is 1% or less. By doing so, a Hafnium silicon oxide film can be obtained as a target film.

The oxide film of the present invention is amorphous and has a high dielectric constant and very excels in a gate oxide film. Particularly, even if the oxide film is thin, the tunnel leak current does not occur so that it becomes hard that a semiconductor element operates erroneously.

Moreover, since the film is obtained through the CVD process, not through the PVD process, there is nearly no potential to impair the substrate. Moreover, the film can be formed neatly, regardless of the presence of differences in step height. Moreover, the high film-forming efficiency leads to a reduced manufacturing cost.

### BRIEF DESCRIPTION OF DRAWINGS

This and other objects, features and advantages of the present invention will become more apparent upon a reading of the following detailed description and drawings, in which:

FIG. 1 is a schematic diagram illustrating a CVD apparatus; and

FIG. 2 is a schematic diagram illustrating a CVD apparatus.

### DESCRIPTION OF THE EMBODIMENTS

The film forming method according to the present invention relates to a Hf—Si oxide film forming method, particularly, to a gate oxide film forming method. The film is formed by the chemical vapor deposition method.

A Si source and a Hf source are used as materials for forming the Hf—Si oxide film.

Si(OR)₄ (where R is a hydrocarbon group) is used as the Si source. Particularly, R in the Si compound is an alkyl group having a carbon number of 1 to 12 (preferably 1 to 5). A chemical compound selected from the group consisting of Si(OC₂H₅)₄ and Si(OCH₃)₄ is preferable as the Si compound.

Hf(NR′R″)₄, where R′, R″ is a hydrocarbon group or a silicon series compound group, each which has the same type or a different type, is used as the Hf source. Particularly, R′, R″ in the Hf compound is an alkyl group having a carbon number of 1 to 12 (preferably 1 to 5). A chemical compound selected from the group consisting of Hf(N(C₂H₅)₂)₄, Hf(N(CH₃)₂)₄ and Hf(N(C₂H₅)CH₃)₄ is preferably as the Hf compound.

In the most preferable case, Hf(N(C₂H₅)₂)₄ and Si(OC₂H₅)₄ are used.

The Si source (Si compound) and the Hf source (Hf compound) are supplied, decomposed and deposited, so that a Hf—Si oxide film is formed on the substrate.

The Si(OR)₄ and Hf(NR′R″)₄ are supplied simultaneously or separately. The film forming process is carried out in an oxidizing atmosphere. In the CVD process, the substrate is maintained at 450° C. to 650° C.

A preferable supply ratio (weight ratio) between the Hf(NR′R″)₄ and the Si(OR)₄ is 1:100 to 1000:1 (=the former:the latter). Particularly, a preferable supply ratio (weight ratio) between the Hf(NR′R″)₄ and the Si(OR)₄ is 1:50 to 100:1 (=the former:the latter). This ratio is selected to select a preferable gate oxide film (a gate oxide film made of a Hf—Si oxide).

The above-mentioned film contains Hf, Si and O as principal components. C contained in the film is at most one atomic % (particularly, 0.5 atomic %).

According to the present invention, the semiconductor elements have the above-mentioned films, particularly, as gate oxide films.

Specific embodiments will be described below.

Embodiment 1:

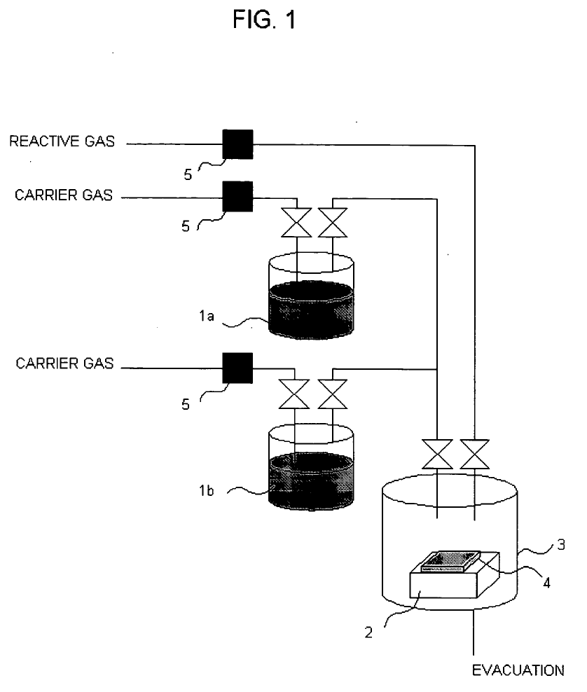

FIG. 1 is a schematic diagram illustrating a CVD apparatus embodying a chemical vapor deposition process according to the present invention.

Referring to FIG. 1, numeral 1a, 1b represents a container, 2 represents a heater, 3 represents a decomposition reactor, 4 represents a Si substrate, and 5 represents a gas flow controller. This CVD apparatus is well known and hence the duplicate explanation will be omitted here.

Using the CVD apparatus shown in FIG. 1, a Hf—Si—O film (Hafnium silicon oxide film) was formed on the Si substrate 4.

That is, Hf(NEt₂)₄ is placed in the container 1a and Si(OEt)₄ is placed in the container 1b. The inside of the container 1a is maintained at 80° C. while the inside of the container 1b is maintained at 0° C. A carrier gas is supplied at a ratio of 20 ml/min into the container 1a, 1b. At the same time, oxygen is introduced as a reactive gas at a ratio of 60 ml/min or less.

The vaporized Hf(NEt₂)₄ and Si(OEt)₄ and oxygen were introduced into the decomposition reactor 3 via the conduit, together with the carrier gas. At this time, the system is evacuated in vacuum. The heater 2 heats the Si substrate 4 at 550° C. to 600° C.

By doing so, an oxide film (gate oxide film) was formed on the Si substrate 4.

The oxide film was subjected to an elemental analysis. The result showed that the film is formed of Hf, Si and O. The amount of C in the film was less than 1%. The amount of N was less than 0.1%. That is, the film was substantially formed of Hf, Si and O. Hf:Si=1:0.46 to 3.8 (in atomic number ratio). Hf:O=1:2.45 to 16.6 (in atomic number ratio).

The ratio between Hf and Si contained in the film is controlled based on the ratio between Hf(NEt₂)₄ and Si(OEt)₄, supplied to the decomposition reactor 3. In other words, in order to increase the Hf amount in the film, Hf(NEt₂)₄ supplied to the decomposition reactor 3 is increased. In contrast, in order to increase the Si amount in the film, Si(OEt)₄ supplied to the decomposition reactor 3 is increased.

In addition, even when the ratio between Hf(NEt₂)₄ and Si(OEt)₄ was constant, the ratio between Hf and Si in the film could be changed by controlling the film forming temperature. That is, the Si amount increased at high film forming temperatures.

The ratio of O contained in the film can be controlled through adjusting the amount of oxygen to be supplied.

In the observation under the cross-sectional TEM (transmission electron microscope), the interface between the silicon substrate 4 and the oxide film was smooth. Moreover, it was confirmed that the silicon substrate 4 was not in a damaged state.

### COMPARATIVE EXAMPLE 1

In the embodiment 1, a similar process was carried out using Si(NCO)₄, instead of Si(OEt)₄.

The film obtained in the comparative example was subjected to an elemental analysis. As a result, the amount of C, N was more than ten times or more that in the embodiment 1. In other words, there was a great amount of impurities.

### COMPARATIVE EXAMPLE 2

In the embodiment 1, a similar process was carried out using HSi(NEt₂)₃, instead of Si(OEt)₄.

The film obtained in the present comparative example was subjected to an elemental analysis. As a result, the amount of C, N was more than ten times or more that in the embodiment 1. In other words, there was a great amount of impurities.

### COMPARATIVE EXAMPLE 3

In the embodiment 1, a similar process was carried out using Hf(t-OBu)₄, instead of Hf(NEt₂)₄.

The film obtained in the present comparative example was subjected to an elemental analysis. As a result, the amount of C was more than ten times or more that in the embodiment 1. In other words, there was a great amount of impurities.

Embodiment 2:

In the embodiment 1, a similar process was carried out, but Hf(NEtMe)₄ was used instead of Hf(NEt₂)₄ and the temperature of the container 1a was set at 65° C. Thus, the oxide film (gate oxide film) was formed on the Si substrate 4.

The resultant film was subjected to an elemental analysis. The result proved that the film was formed of Hf, Si and O. The amount of C in the film was less than 1% and the amount of N was less than 0.1%. That is, the film was substantially formed of Hf, Si and O. Hf:Si=1:0.39 to 4.6 (in atomic number ratio). Hf:O=1:1.98 to 18.3 (in atomic number ratio).

In the observation under the cross-sectional TEM, the interface between the silicon substrate 4 and the oxide film is smooth. Moreover, it was confirmed that the silicon substrate 4 was not in a damaged state.

Embodiment 3:

A similar process was carried out in the embodiment 1 but Hf(NMe₂)₄ was used instead of Hf(NEt₂)₄ and the temperature of the container 1a was 50° C. Thus, the oxide film (gate oxide film) was formed on the Si substrate 4.

The resultant film was subjected to an elemental analysis. The result proved that the film is formed of Hf, Si and O. The amount of C in the film was less than 1% and the amount of N was less than 0.1%. That is, the film was substantially formed of Hf, Si and O. Hf:Si=1:0.32 to 5.9 (in atomic number ratio). Hf:O=1:2.07 to 15.4 (in atomic number ratio).

In the observation under the cross-sectional TEM, the interface between the silicon substrate 4 and the oxide film was smooth. Moreover, it was confirmed that the silicon substrate 4 was not in a damaged state.

Embodiment 4:

A similar process was carried out in the embodiment 1 but Si(OMe)₄ was used instead of Si(OEt)₄ and the temperature of the container 1b was −10° C. Thus, the oxide film (gate oxide film) was formed on the Si substrate 4.

The resultant film was subjected to an elemental analysis. The result proved that the film is formed of Hf, Si and O. The amount of C in the film was less than 1% and the amount of N was less than 0.1%. That is, the film was substantially formed of Hf, Si and O. Hf:Si=1:0.29 to 9.2 (in atomic number ratio). Hf:O=1:2.88 to 22.5 (in atomic number ratio).

In the observation under the cross-sectional TEM, the interface between the silicon substrate 4 and the oxide film is smooth. Moreover, it was confirmed that the silicon substrate 4 was not in a damaged state.

Embodiment 5:

A similar process was carried out in the embodiment 2 but Si(OMe)₄ was used instead of Si(OEt)₄ and the temperature of the container 1b was −10° C. Thus, the oxide film (gate oxide film) was formed on the Si substrate 4.

The resultant film was subjected to an elemental analysis. The result proved that the film is formed of Hf, Si and O. The amount of C in the film was less than 1% and the amount of N was less than 0.1%. That is, the film was substantially formed of Hf, Si and O. Hf:Si=1:0.35 to 10.2 (in atomic number ratio). Hf:O=1:2.61 to 21.6 (in atomic number ratio).

In the observation under the cross-sectional TEM, the interface between the silicon substrate 4 and the oxide film was smooth. Moreover, it was confirmed that the silicon substrate 4 was not in a damaged state.

Embodiment 6:

A similar process was carried out in the embodiment 3 but Si(OMe)₄ was used instead of Si(OEt)₄ and the temperature of the container 1b was −10° C. Thus, an oxide film (gate oxide film) was formed on the Si substrate 4.

The resultant film was subjected to an elemental analysis. The result proved that the film is formed of Hf, Si and O. The amount of C in the film was less than 1% and the amount of N was less than 0.1%. That is, the film was substantially formed of Hf, Si and O. Hf:Si=1:0.43 to 6.1 (in atomic number ratio). Hf:O=1:3.11 to 17.6 (in atomic number ratio).

In the observation under the cross-sectional TEM, the interface between the silicon substrate 4 and the oxide film was smooth. Moreover, it was confirmed that the silicon substrate 4 was not in a damaged state.

Embodiment 7:

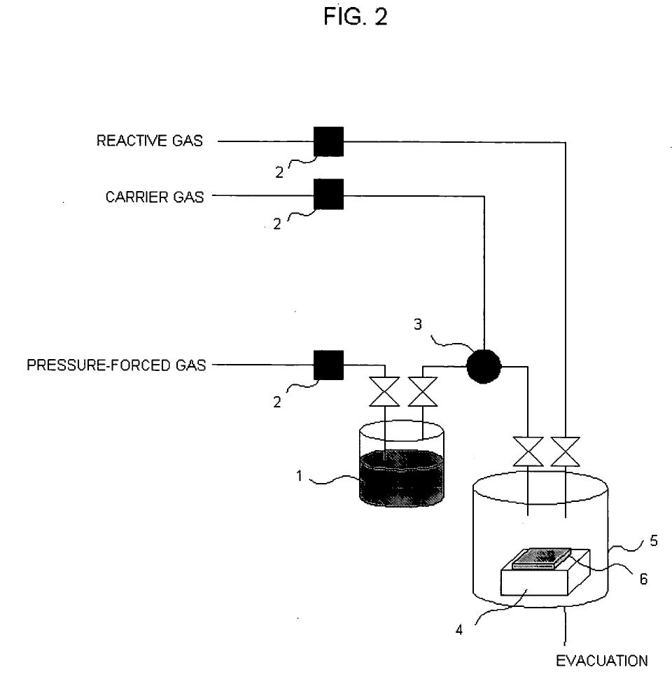

FIG. 2 is a schematic diagram illustrating a CVD apparatus embodying the chemical vapor deposition process according to the present invention.

Referring to FIG. 2, numeral 1 represents a container, 2 represents a gas flow controller, 3 represents a vaporizer, 4 represents a heater, 5 represents a decomposition reactor, and 6 represents a Si substrate. Such a CVD apparatus is well known and hence the detail explanation will be omitted here.

Using the CVD apparatus shown in FIG. 2, a Hf—Si—O film (Hafnium silicon oxide film) was formed on the Si substrate 6.

That is, a mixture of Hf(NEt₂)₄ and Si(OEt)₄ (Hf(NEt₂)₄:Si (OEt)₄=0.01 to 1000:1) is introduced into the container 1. The mixture is sent to the vaporizer 3 via the liquid flow controller and is vaporized at 120° C.

The Hf(NEt₂)₄ and Si(OEt)₄, vaporized, are introduced into the decomposition reactor 5 via the conduit, together with the carrier gas. At the same time, oxygen is introduced as a reactive gas into the decomposition reactor 5. The Si substrate 6 is heated at 550° C. to 600° C.

Thus, the oxide film (gate oxide film) was formed on the Si substrate 6.

The resultant film was subjected to an elemental analysis. The result proved that the film is formed of Hf, Si and O. The amount of C in the film was less than 1% and the amount of N was less than 0.1%. That is, the film was substantially formed of Hf, Si and O. Hf Si=1:0.32 to 3.3 (in atomic number ratio). Hf:O=1:2.79 to 14.3 (in atomic number ratio).

In the observation under the cross-sectional TEM, the interface between the silicon substrate 6 and the oxide film was smooth. Moreover, it was confirmed that the silicon substrate 6 was not in a damaged state.

Particularly, the present invention can be usefully applied in the semiconductor fields.

1 A method for forming Hf—Si oxide films through a chemical vapor deposition process, wherein one or more chemical compounds represented with Si(OR)₄, where R is a hydrocarbon group, are used as said Si source; and wherein one or more chemical compound represented with Hf(NR′R″)₄, where R′, R″ is a hydrocarbon group or a silicon series compound group, each which has the same type or a different type, are used as said Hf source.

2 The film forming method as claimed in claim 1, comprising steps of:
supplying said Si(OR)₄;
supplying said Hf(NR′R″)₄; and
decomposing a chemical compound supplied in said supply steps to deposit Hf and Si on a substrate and thus forming a Hf—Si oxide film on said substrate.

3 The film forming method as claimed in claim 1, wherein said Si(OR)₄ and said Hf(NR′R″)₄ are supplied simultaneously.

4 The film forming method as claimed in claim 1, wherein said Si(OR)₄ and said Hf(NR′R″)₄ are supplied separately.

5 The film forming method as claimed in claim 1, wherein said film forming is carried out in an oxidizing atmosphere.

6 The film forming method as claimed in claim 1, wherein said film is a semiconductor gate oxide film.

7 The film forming method as claimed in claim 1, wherein R in said Si(OR)₄ is an alkyl group having a carbon number of 1 to 12 and wherein R′, R″ in said Hf(NR′R″)₄ is an alkyl group having a carbon number of 1 to 12.

8 The film forming method as claimed in claim 1, wherein said Si(OR)₄ is a chemical compound selected from Si (OC₂H₅)₄ and Si(OCH₃)₄.

9 The film forming method as claimed in claim 1, wherein said Hf(NR′R″)₄ is a chemical compound selected from Hf(N(C₂H₅)₂)₄, Hf(N(CH₃)₂)₄, and Hf(N(C₂H₅)CH₃)₄.

10 The film forming method as claimed in claim 1, wherein said film contains Hf, Si and O as principal components and contains C having a trace amount of less than one atom %.

11 A film formed through a chemical vapor deposition process, wherein one or more chemical compounds represented with Si(OR)₄, where R is a hydrocarbon group, are used as a Si source; and wherein one or more chemical compounds represented with Hf(NR′R″)₄, where R′, R″ is a hydrocarbon group or a silicon series compound group, each which has the same type or a different type, are used as a Hf source; and wherein said film contains Hf, Si and O as principal components and contains C having a trace amount of less than one atom %.

12 The film as claimed in claim 11, wherein said film is formed by steps of:
supplying said Si(OR)₄;
supplying said Hf(NR′R″)₄; and
decomposing a chemical compound supplied in said supply steps to deposit Hf and Si on a substrate and thus forming a Hf—Si oxide film on said substrate.

13 The film as claimed in claim 11, wherein said Si(OR)₄ and said Hf(NR′R″)₄ are supplied simultaneously.

14 The film as claimed in claim 11, wherein said Si(OR)₄ and said Hf(NR′R″)₄ are supplied separately.

15 The film as claimed in claim 11, wherein said film forming is carried out in an oxidizing atmosphere.

16 The film as claimed in claim 11, wherein said film is a semiconductor gate oxide film.

17 A film forming material being a material for forming a film through a chemical vapor deposition process, said film forming material containing Si(OR)₄, where R is a hydrocarbon group, and Hf(NR′R″)₄, where R′, R″ is a hydrocarbon group or a silicon series compound group, each which has the same type or a different type.

18 The film forming material as claimed in claim 17, wherein R in said Si(OR)₄ is an alkyl group having a carbon number of 1 to 12 and wherein R′, R″ in said Hf(NR′R″)₄ is an alkyl group having a carbon number of 1 to 12.

19 The film forming material as claimed in claim 17, wherein said Si(OR)₄ is a chemical compound selected from Si(OC₂H₅)₄ and Si(OCH₃)₄.

20 The film forming material as claimed in claim 17, wherein said Hf(NR′R″)₄ is a chemical compound selected from Hf(N(C₂H₅)₂)₄, Hf(N(CH₃)₂)₄, and Hf (N(C₂H₅)CH₃)₄.

21 The film forming material as claimed in claim 17, wherein said film to be formed is a gate oxide film.
